(19) United States
(12) Patent Application Publication
(10) Pub. No.: US 2026/0123447 A1
(43) Pub. Date: Apr. 30, 2026

(54) GLASS-BASED CHIP-EMBEDDED PRINTED CIRCUIT BOARDS AND METHODS OF MANUFACTURING THE SAME

(71) Applicant: Toyota Motor Engineering & Manufacturing North America, Inc., Plano, TX (US)

(72) Inventors: Tianzhu Fan, Houston, TX (US); Feng Zhou, Ann Arbor, MI (US); Shailesh N. Joshi, Ann Arbor, MI (US); Yohei Iwahashi, South Lyon, MI (US); Ercan Mehmet Dede, Ann Arbor, MI (US)

(21) Appl. No.: 18/931,544

(22) Filed: Oct. 30, 2024

(51) Int. Cl. H01L 21/48; H01L 23/00

(52) U.S. Cl. CPC H10W 70/05; H10W 40/037; H10W 70/095; H10W 80/327

(57) ABSTRACT

A method for manufacturing an asymmetric chip-embedded printed circuit board (PCB) includes bonding a bare die to a heat spreader and bonding the heat spreader to a cold plate. The method further includes forming an electrically conductive layer on a glass substrate, etching a conductive pattern on the glass substrate, forming through conductive vias in the glass substrate, and bonding a first surface of the glass substrate to the cold plate. The method further includes bonding a plurality of additional glass substrates with conductive patterns to a second side of the glass substrate and forming through conductive vias in the plurality of additional glass substrates such that an asymmetric glass-based chip-embedded printed circuit board is formed.

### TECHNICAL FIELD

The present disclosure relates to printed circuit boards, and particularly to printed circuit boards with integrated circuits embedded therein.

### BACKGROUND

Printed circuit boards (PCBs) are typically used for mechanical support and electrical connection of electronic components using conductive pathways of copper sheets laminated onto a non-conductive substrate. And multi-layer PCBs provide higher capacity and/or density of electronic components in a smaller footprint by incorporating two or more layers. However, the design and/or manufacture of multilayer PCBs can be difficult.

The present disclosure addresses issues related to the manufacture of multi-layer PCBs and other issues related to multi-layer PCBs.

### SUMMARY

This section provides a general summary of the disclosure and is not a comprehensive disclosure of its full scope or all of its features.

In one form of the present disclosure, a method includes bonding a bare die to a heat spreader, bonding the heat spreader to a cold plate, forming an electrically conductive layer on a glass substrate, etching a conductive pattern on the glass substrate, forming through conductive vias in the glass substrate, bonding a first surface of the glass substrate to the cold plate, bonding a plurality of additional glass substrates with conductive patterns to a second side of the glass substrate, and forming through conductive vias in the plurality of additional glass substrates such that an asymmetric glass-based chip-embedded printed circuit board is formed.

In another form of the present disclosure, a method includes bonding a bare die to a heat spreader, bonding the heat spreader to a heat spreader cave in a cold plate, forming an electrically conductive layer on a glass substrate, etching a conductive pattern on the glass substrate, forming through conductive vias in the glass substrate, bonding a first side of the glass substrate to the cold plate, bonding a plurality of additional glass substrates with conductive patterns to a second side of the glass substrate, and forming through conductive vias in the plurality of additional glass substrates such that an asymmetric glass-based chip-embedded is formed.

In still another form of the present disclosure, a method includes forming an electrically conductive layer on a glass substrate, etching a conductive pattern on the glass substrate, forming through conductive vias in the glass substrate, forming a heat spreader cave in the glass substrate, bonding a bare die to a heat spreader, bonding the heat spreader to the heat spreader cave, bonding a first side of the glass substrate to a cold plate, bonding a plurality of additional glass substrates with conductive patterns to a second side of the glass substrate, and forming through conductive vias in the plurality of additional glass substrates such that an asymmetric glass-based chip-embedded is formed.

Further areas of applicability and various methods of enhancing the above technology will become apparent from the description provided herein. The description and specific examples in this summary are intended for purposes of illustration only and are not intended to limit the scope of the present disclosure.

### BRIEF DESCRIPTION OF THE DRAWINGS

The present teachings will become more fully understood from the detailed description and the accompanying drawings, wherein:

FIG. 1 shows a side cross-sectional view of a glass-based chip-embedded printed circuit board (PCB) according to one form of the present disclosure;

FIG. 1A illustrates a step in manufacturing the glass-based chip-embedded PCB in FIG. 1;

FIG. 1B illustrates another step in manufacturing the glass-based chip-embedded PCB in FIG. 1;

FIG. 1C illustrates still another step in manufacturing the glass-based chip-embedded PCB in FIG. 1;

FIG. 1D illustrates yet another step in manufacturing the glass-based chip-embedded PCB in FIG. 1;

FIG. 1E illustrates still yet another step in manufacturing the glass-based chip-embedded PCB in FIG. 1;

FIG. 1F illustrates a plane view of a plurality of bare die-heat spreader assemblies disposed within heat spreader caves and bonded to a glass substrate according to the steps illustrated in FIGS. 1A-1E;

FIG. 1G illustrates a step in manufacturing the glass-based chip-embedded PCB in FIG. 1;

FIG. 1H illustrates another step in manufacturing the glass-based chip-embedded PCB in FIG. 1;

FIG. 1I illustrates still another step in manufacturing the glass-based chip-embedded PCB in FIG. 1;

FIG. 1J illustrates yet another step in manufacturing the glass-based chip-embedded PCB in FIG. 1;

FIG. 1K illustrates still yet another step in manufacturing the glass-based chip-embedded PCB in FIG. 1;

FIG. 1L illustrates a step in manufacturing the glass-based chip-embedded PCB in FIG. 1;

FIG. 1M illustrates another step in manufacturing the glass-based chip-embedded PCB in FIG. 1;

FIG. 1N illustrates still another step in manufacturing the glass-based chip-embedded PCB in FIG. 1;

FIG. 1O illustrates yet another step in manufacturing the glass-based chip-embedded PCB in FIG. 1;

FIG. 2 shows a side cross-sectional view of a glass-based chip-embedded PCB according to another form of the present disclosure;

FIG. 2A illustrates a step in manufacturing the glass-based chip-embedded PCB in FIG. 2;

FIG. 2B illustrates another step in manufacturing the glass-based chip-embedded PCB in FIG. 2;

FIG. 2C illustrates still another step in manufacturing the glass-based chip-embedded PCB in FIG. 2;

FIG. 2D illustrates yet another step in manufacturing the glass-based chip-embedded PCB in FIG. 2;

FIG. 2E illustrates still yet another step in manufacturing the glass-based chip-embedded PCB in FIG. 2;

FIG. 3 shows a side cross-sectional view of a glass-based chip-embedded PCB according to still another form of the present disclosure;

FIG. 3A illustrates a step in manufacturing the glass-based chip-embedded PCB in FIG. 3;

FIG. 3B illustrates another step in manufacturing the glass-based chip-embedded PCB in FIG. 3;

FIG. 3C illustrates still another step in manufacturing the glass-based chip-embedded PCB in FIG. 3;

FIG. 3D illustrates yet another step in manufacturing the glass-based chip-embedded PCB in FIG. 3;

FIG. 3E illustrates still yet another step in manufacturing the glass-based chip-embedded PCB in FIG. 3; and

FIG. 4 shows a side cross-sectional view of a glass-based chip-embedded PCB according to yet another form of the present disclosure.

It should be noted that the figures set forth herein are intended to exemplify the general characteristics of the methods and devices among those of the present technology, for the purpose of the description of certain aspects. The figures may not precisely reflect the characteristics of any given aspect and are not necessarily intended to define or limit specific forms or variations within the scope of this technology.

### DETAILED DESCRIPTION

The present disclosure provides glass-based chip-embedded printed circuit boards (PCBs) and methods of manufacturing glass-based chip-embedded PCBs. As used herein, the term “glass” refers to an amorphous or non-crystalline solid that is transparent and chemically inert, the phrase “chemically inert” refers to not being chemically reactive or active with materials and/or chemicals used during the manufacture and/or usage of PCBs, and the phrase “glass-based chip-embedded PCB” refers to a multi-layer PCB module or unit with two or more glass substrates, two or more power semiconductor devices (also known as a “chip” and referred to herein simply as “power device” or “power devices”), control/drive/protection electronic circuitry, and passive components. Also, as used herein, the phrase “power device” refers to a semiconductor device used as a switch or rectifier in power electronics.

Glass-based chip-embedded PCBs according to the teachings of the present disclosure can include a cold plate with two or more glass substrates bonded to the cold plate, and two or more power devices embedded within one of the glass substrates and/or the cold plate. For example, in some variations, the two or more power devices are disposed at least partially within a glass substrate to form a glass-based core layer, a first surface of the glass core layer is bonded directly to the cold plate, and additional glass substrates, with conductive patterns, are bonded to a second surface, oppositely disposed or positioned from the first surface of the glass-based core player. In other variations, two or more power devices are disposed at least partially within a glass substrate to form a glass-based core layer, one or more glass substrates, with conductive patterns, are bonded between and to a cold plate and a first surface of the glass core layer, and one or more glass substrates, with conductive patterns, are bonded to a second surface, oppositely disposed or positioned from the first surface, of the glass-based core layer. And in still other variations, two or more power devices are disposed at least partially within a cold plate, and two or more glass substrates, with conductive layers, are bonded to the cold plate.

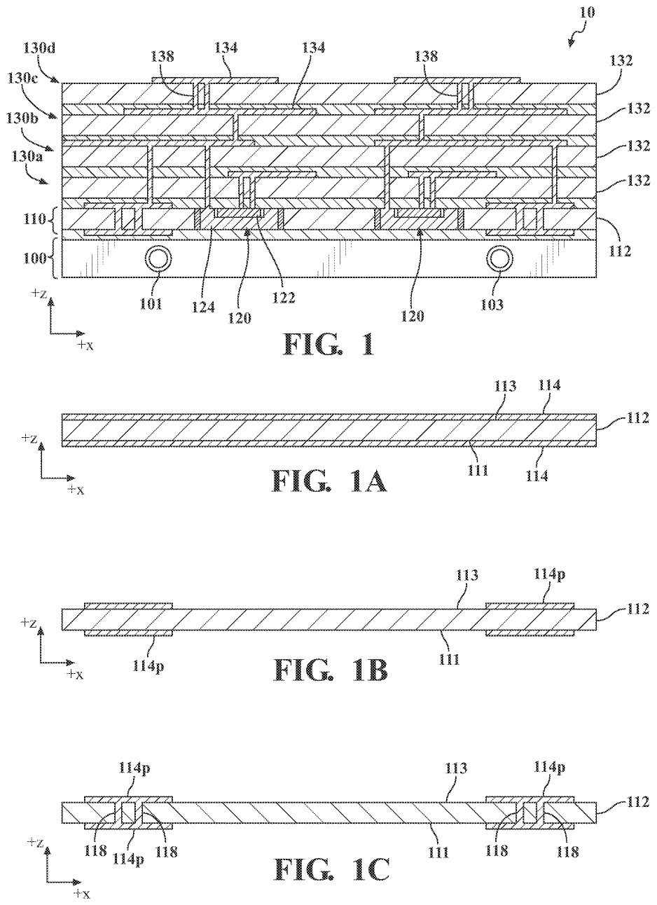

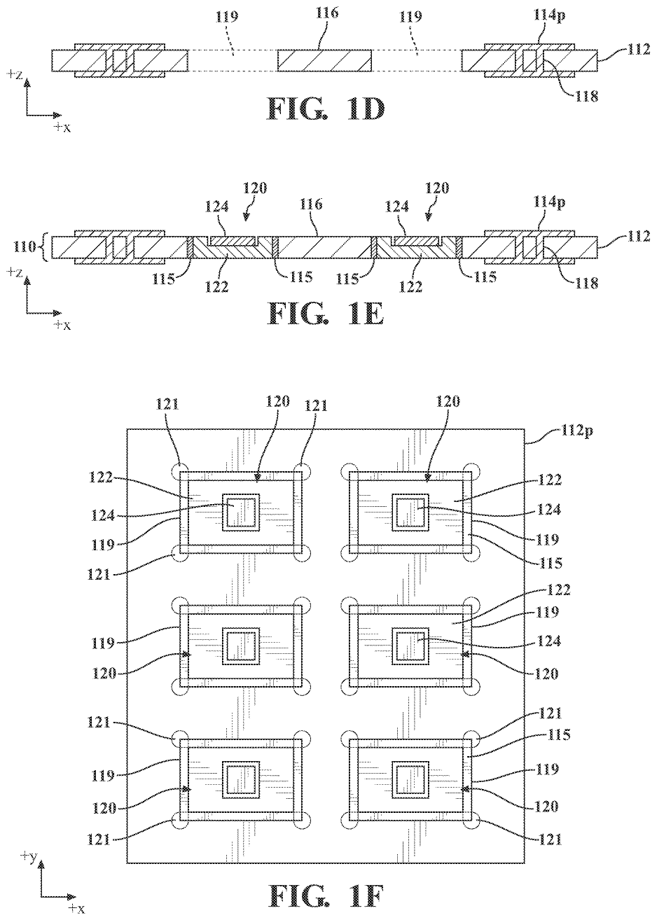

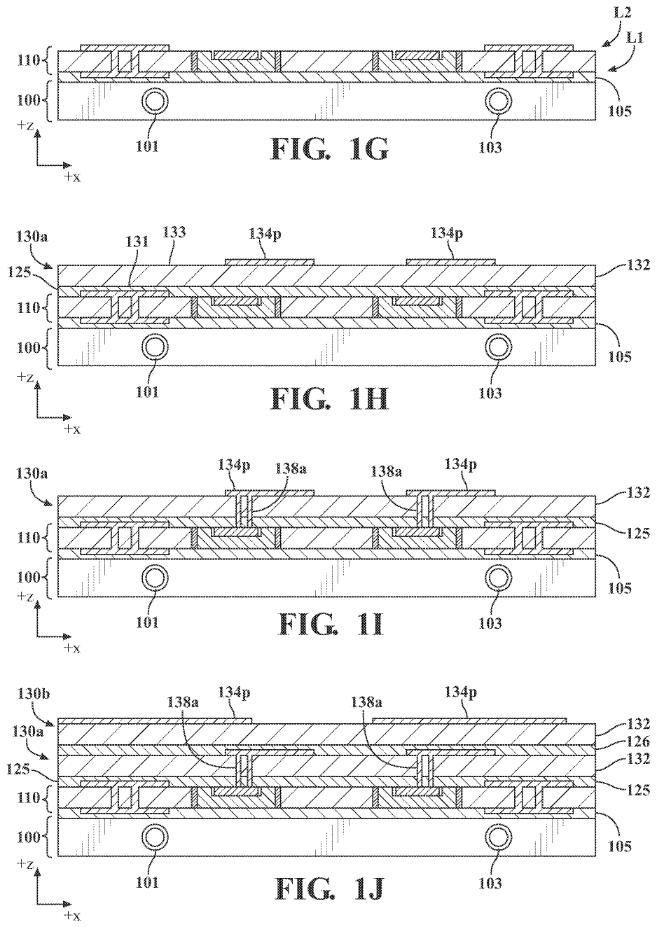

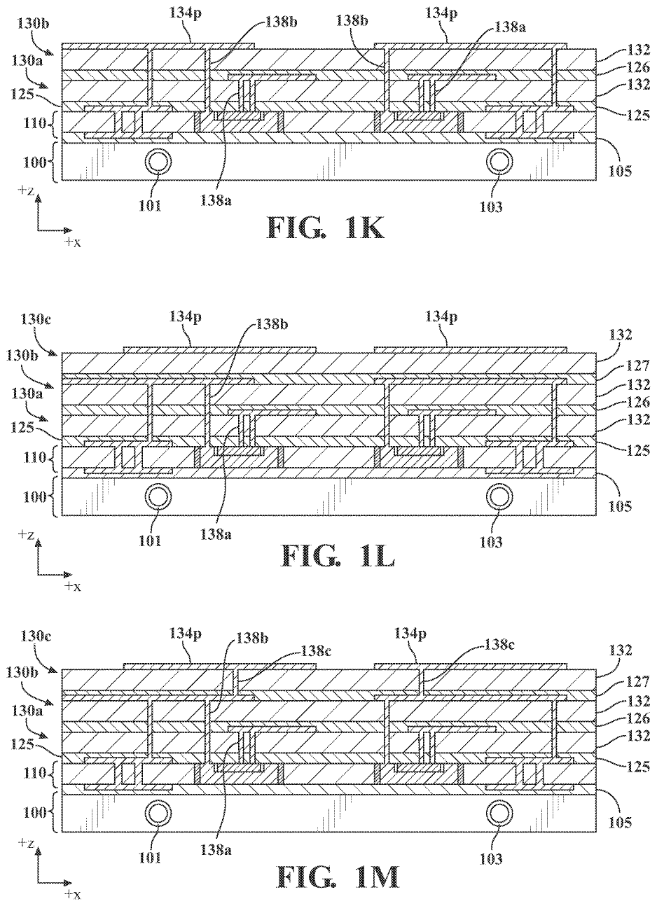

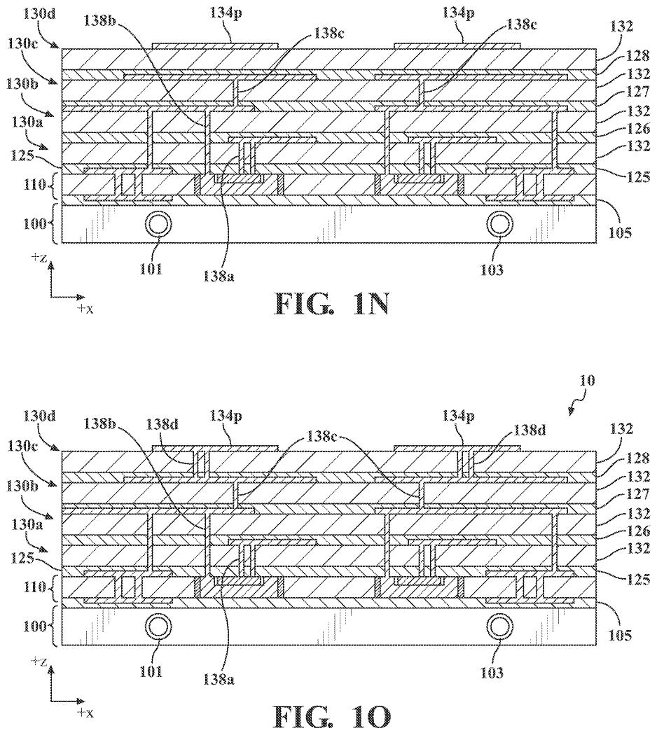

Referring now to FIG. 1, a cross-sectional view of an asymmetric PCB in the form of a glass-based chip-embedded PCB 10 is shown. As used herein, the phrase “asymmetric PCB” refers to a PCB with a core layer not evenly positioned or disposed between a plurality of circuit board layers. That is, there are a greater number of circuit board layers bonded to one side of the core layer than are bonded to an opposite side of the core layer. As used herein, the phrase “core layer” refers to a layer of the glass-based chip-embedded PCB 10 that includes the two or more power devices and the phrase “circuit board layer” refers to a PCB layer or substrate with control/drive/protection electronic circuitry and/or passive components, but without a power device embedded therein. Also, it should be understood that PCBs formed from traditional materials (e.g., FR4) typically require the manufacture of symmetric chip-embedded PCBs, i.e., a core layer evenly positioned or disposed between a plurality of circuit board layers due to a lack of stiffness thereof and the PCB manufacturing process resulting in warping of the circuit board layers. In contrast, the stiffness (i.e., elastic modulus) of the glass substrates according to the teachings of the present disclosure allows for the manufacture of asymmetric chip-embedded PCBs without warping.

The glass-based chip-embedded PCB 10 includes a cold plate 100 (not shown in cross-section in the figures), a glass-based core layer 110 and a plurality of glass-based circuit board layers 130a-130d (collectively referred to herein as “glass-based circuit board layers 130”). As used herein, the phrase “cold plate” refers to a device that removes heat from electronic components and other surfaces with high heat loads. That is, a cold plate provides localized cooling of power electronics, e.g., by transferring heat from the power electronics to a remote heat exchanger. In some variations, the cold plate 100 is a fluid (e.g., air or water) cooled cold plate 100 with a fluid inlet 101 and a fluid outlet 103. In other variations, the cold plate 100 is a two-phase cooling device, a vapor chamber, or an air-cooled heat sink.

The glass-based core layer 110 includes a glass substrate 112 with two or more bare die-heat spreader assemblies 120 embedded therein. Each of the bare die-heat spreader assemblies 120 includes a bare die 122 (i.e., a power device) bonded to and in thermal and electrical contact with a heat spreader 124. Each of the glass-based circuit board layers 130 includes a glass substrate 132 (also referred to herein as “glass layer 132”), control/drive/protection electronic circuitry 134 (also referred to herein simply as “conductive pattern 134”), and one or more conductive through vias 138 extending between a lower (−z direction) surface and an upper (+z direction) surface of a given glass layer 132. In some variations, one or more of the conductive through vias 138 is in direct contact with a bare die 122 (i.e., a power device) of a bare die-heat spreader assembly 120 and one or more of the conductive through vias 138 is in direct contact with a heat spreader 124 of a bare die-heat spreader assembly 120. In this manner current and electrical signals can be transmitted to and received from the bare dies 122 of the bare die-heat spreader assemblies 120 such that data and instructions provide for the exchange of information between the bare dies 122 and other electrical components.

Referring to FIGS. 1A-IN, steps for the manufacture of the glass-based chip-embedded PCB 10 according to one method are illustrated. With reference to FIG. 1A, one step of manufacturing the glass-based chip-embedded PCB 10 includes forming an electrically conductive layer 114 (also referred to herein simply as “conductive layer 114”) on a first surface 111 and/or on a second surface 113 of a glass substrate 112. The glass substrate 112 has a predefined thickness (z-direction), width (x-direction), and length (y-direction). In some variations, the glass substrate has a thickness between about 0.5 millimeters (mm) and about 5.0 mm. The conductive layer 114 is formed or applied to the glass substrate 112 using any method or technique known or yet to be discovered, including chemical vapor deposition (CVD), physical vapor deposition (PVD), sputtering coating, directed bonded copper (DBC), direct plated copper (DPC), stencil/vacuum plating, screen printing, and inkjet printing, among others. Also, the conductive layer 114 is formed from an electrically conducting material (e.g., copper (Cu), silver (Ag), or alloys thereof) and has a predefined thickness between about 35 micrometers (μm) and about 105 μm.

Referring to FIGS. 1B-1C, additional steps for the manufacture of the glass-based chip-embedded PCB 10 include etching the conductive layer 114 to form a predefined conductive pattern 114p on the first surface 111 and/or on the second surface 113 of the glass substrate 112 (FIG. 1B) and forming conductive through vias 118 through the glass substrate 112 (FIG. 1C). In some variations, etching the conductive layer 114 to form the predefined conductive pattern 114p includes applying resist to the first surface 111 and/or the second surface 113, exposure and development of the resist, etching, rinsing and cleaning, inspection and quality control, and surface finishing of the exposed glass substrate 112 and/or the conductive pattern 114p. And in at least one variation, forming the conductive through vias 118 through the glass substrate 112 includes alignment, drilling (e.g., laser or mechanical drilling) vias through the conductive pattern 114p and the glass substrate 112, pre-processing the vias (e.g., seed growth on or in the vias), and depositing and filling the vias with a conductive material (e.g., Cu, Ag, or alloys thereof) using electroplating or other deposition method.

With reference to FIG. 1D, another step for the manufacture of the glass-based chip-embedded PCB 10 includes forming heat spreader caves 119 in the glass substrate 112 (FIG. 1D). In some variations, the heat spreader caves 119 are generally rectangular (e.g., square) through-holes in the glass substrate 112. It should be understood that forming the heat spreader caves 119 in the glass substrate 112 can be executed or performed before or after forming the conductive layer 114 on the first surface 111 and/or on the second surface 113 of the glass substrate 112 (FIG. 1A), or before or after forming the predefined conductive pattern 114p on the first surface 111 and/or on the second surface 113 of the glass substrate 112 (FIG. 1B).

Referring to FIG. 1E, another step for the manufacture of the glass-based chip-embedded PCB 10 includes bonding bare die-heat spreader assemblies 120 to the glass substrate 112 to form a glass-based core layer 110. For example, heat spreaders 124, with or without bare dies 122 (i.e., semiconductor chips) bonded thereto, are desirably positioned within and bonded to the heat spreader caves 119, and thereby bonded to the glass substrate 112, with the bonding layer 115. Depending on the bonding technique used to bond the bonding bare die-heat spreader assemblies 120 to the glass substrate 112, the bonding layer 115 can be a metal, a glass, or an adhesive bonding material such as an epoxy resin and an acrylic adhesive, or a thermos-curable bonding material such as a thermosetting epoxy, among others.

In some variations, the bonding layer 115 is a dielectric layer. Materials from which the heat spreaders 124 are formed include materials having similar values (+/−10%) of coefficient of thermal expansion (CTE) as the CTE for the glass substrate 112. Examples of such heat spreader materials include thermal pyrolytic graphite (TGP) and metal such as copper (Cu), Cu alloys, and copper tungsten alloys, among others. Accordingly, in some variations a heat spreader 123 can be metal heat spreaders, carbon heat spreaders, or metal-carbon composite heat spreader. In at least one variations, the heat spreaders 124 are bonded to the glass substrate 112 using high temperature bonding techniques such as active brazing and UV-assisted brazing, middle temperature bonding techniques such as anodic bonding and glass frit bonding, and low-room temperature bonding techniques such as UV-curable adhesive bonding and thermo-curable bonding. Also, in some variations a bare die 122 is bonded to a heat spreader 124 after the heat spreader 124 is bonded to the glass substrate 112, while in other variations, a bare die 122 is bonded to a heat spreader 124 before the heat spreader 124 is bonded to the glass substrate 112.

Referring now to FIG. 1F, in some variations a plurality of glass-based core layers 110 are formed on or in a glass panel 112p per the steps discussed above with respect to FIGS. 1A-1E. That is, a plurality of rows (x-direction) of heat spreader caves 119 are formed in the glass panel 112p and a plurality of heat spreaders 124, with or without bare dies 122 bonded thereto, are desirably positioned at least partially within the heat spreader caves 119 and bonded to the glass panel 112p as illustrated in FIG. 1F. And in such variations, stress relieve structures 121 can be formed at corners of the heat spreader caves 119 such that the initiation and/or propagation of cracks at the corners of the heat spreader caves is inhibited. Also, the glass panel 112p is cut, either before or after the steps discussed below with respect to FIGS. 1G-1O, along the x-direction and/or y-direction shown in the figures to provide a plurality glass-based core layers 110.

Referring to FIG. 1G, another step for the manufacture of the glass-based chip-embedded PCB 10 includes bonding the glass-based core layer 110 to the cold plate 100 with an electrically insulating bonding layer 105. In some variations, the electrically insulating bonding layer 105 is a dielectric layer that is thermally conductive and electrically insulating. And with reference to FIGS. 1H-1I, other steps include bonding a glass-based circuit board layer 130a to the glass-based core layer 110 (FIG. 1H) with an electrically insulating bonding layer 125 and forming conductive through vias 138a through the glass-based circuit board layer 130a (FIG. 1I). It should be understood that the predefined conductive pattern 134p of the glass-based circuit board layer 130a can be etched and formed from a conductive layer 114 before bonding the glass-based circuit board layer 130a to the glass-based core layer 110. In the alternative, the predefined conductive pattern 134p of the glass-based circuit board layer 130a can be etched and formed from a conductive layer 114 after bonding the glass layer 132 that forms the glass-based circuit board layer 130a to the glass-based core layer 110.

In some variations, and as illustrated in FIG. 1I, the conductive through vias 138a are in direct (physical) contact with the bare die 122 of the bare die-heat spreader assemblies 120. The glass-based circuit board layer 130a is formed from a glass layer 132 and has a predefined conductive pattern 134p on a first surface 131 and/or a second surface 133 that is oppositely disposed from the first surface 131. It should be understood that the predefined conductive pattern 134p and the conductive through vias 138a, and other conductive patterns and conductive through vias disclosed herein, can be formed using the steps discussed above with respect to the predefined conductive pattern 114p (FIG. 1B) and conductive through vias 118 (FIG. 1C). In this manner, a first glass-based circuit board layer 130a is added or bonded to the glass-based core layer 110. Also, bonding of the glass-based circuit board layer 130a to the glass-based core layer 110 with the electrically insulating bonding layer 125 can be performed using known or yet to be discovered bonding techniques such as adhesive bonding (UV or thermal curable), glass frit bonding, among others. Accordingly, the electrically insulating bonding layer 125 can be an adhesive layer or a glass frit layer, among others.

Referring to FIGS. 1J-1K, other steps include bonding a glass-based circuit board layer 130b with a conductive pattern 134p to the glass-based circuit board layer 130a (FIG. 1J) with an electrically insulting bonding layer 126 and forming conductive through vias 138b through the glass-based circuit board layer 130b (FIG. 1K), and optionally through the glass-based circuit board layer 130a. The glass-based circuit board layer 130b is formed from a glass layer 132 and has a predefined conductive pattern 134p on a first surface 131 and/or a second surface 133 that is oppositely disposed from the first surface 131. It should be understood that the predefined conductive pattern 134p of the glass-based circuit board layer 130b can be etched and formed from a conductive layer 114 before bonding the glass-based circuit board layer 130b to the glass-based circuit board layer 130a. In the alternative, the predefined conductive pattern 134p of the glass-based circuit board layer 130b can be etched and formed from a conductive layer 114 after bonding the glass layer 132 that forms the glass-based circuit board layer 130b to the glass-based circuit board layer 130a.

In some variations, and as illustrated in FIG. 1K, the conductive through vias 138b extend through the glass-based circuit board layer 130a and are in direct contact with the heat spreader 124 of the bare die-heat spreader assemblies 120. It should be understood that bonding of the glass-based circuit board layer 130b to the glass-based circuit board layer 130a with the electrically insulting bonding layer 126 can include the steps discussed above with respect to bonding the glass-based circuit board layer 130a to the glass-based core layer 110 with the electrically insulting bonding layer 125. In this manner, a second glass-based circuit board layer 130b is added or bonded to the first glass-based circuit board layer 130a.

Referring to FIGS. 1L-IM, other steps include bonding a glass-based circuit board layer 130c to the glass-based circuit board layer 130b (FIG. 1L) with an electrically insulting bonding layer 127 and forming conductive through vias 138c through the glass-based circuit board layer 130c (FIG. 1M). The glass-based circuit board layer 130c is formed from a glass layer 132 and has a predefined conductive pattern 134p on a first surface 131 and/or a second surface 133 that is oppositely disposed from the first surface 131. It should be understood that the predefined conductive pattern 134p of the glass-based circuit board layer 130c can be etched and formed from a conductive layer 114 before bonding the glass-based circuit board layer 130c to the glass-based circuit board layer 130b. In the alternative, the predefined conductive pattern 134p of the glass-based circuit board layer 130c can be etched and formed from a conductive layer 114 after bonding the glass layer 132 that forms the glass-based circuit board layer 130c to the glass-based circuit board layer 130b. It should also be understood that bonding of the glass-based circuit board layer 130c to the glass-based circuit board layer 130b with the electrically insulting bonding layer 127 can include the steps discussed above with respect to bonding the glass-based circuit board layer 130a to the glass-based core layer 110 with the electrically insulating bonding layer 125. In this manner, a third glass-based circuit board layer 130c is added or bonded to the second glass-based circuit board layer 130b.

Referring to FIGS. 1N-1O, other steps include bonding a glass-based circuit board layer 130d to the glass-based circuit board layer 130c (FIG. 1L) with an electrically insulating bonding layer 128 and forming conductive through vias 138d through the glass-based circuit board layer 130d (FIG. 1N). The glass-based circuit board layer 130d is formed from a glass layer 132 and has a predefined conductive pattern 134p on a first surface 131 and/or a second surface 133 that is oppositely disposed from the first surface 131. It should be understood that the predefined conductive pattern 134p of the glass-based circuit board layer 130d can be etched and formed from a conductive layer 114 before bonding the glass-based circuit board layer 130d to the glass-based circuit board layer 130c. In the alternative, the predefined conductive pattern 134p of the glass-based circuit board layer 130d can be etched and formed from a conductive layer 114 after bonding the glass layer 132 that forms the glass-based circuit board layer 130d to the glass-based circuit board layer 130c. It should also be understood that bonding of the glass-based circuit board layer 130d to the glass-based circuit board layer 130c with the electrically insulting bonding layer 128 can include the steps discussed above with respect to bonding the glass-based circuit board layer 130a to the glass-based core layer 110 with the electrically insulating bonding layer 125. In this manner, a fourth glass-based circuit board layer 130d is added or bonded to the third glass-based circuit board layer 130c and the manufacture of the glass-based chip-embedded PCB 10. However, it should be understood that glass-based chip-embedded PCBs according to the teachings of the present disclosure can have less than four glass-based circuit board layers or more than four glass-based circuit board layers.

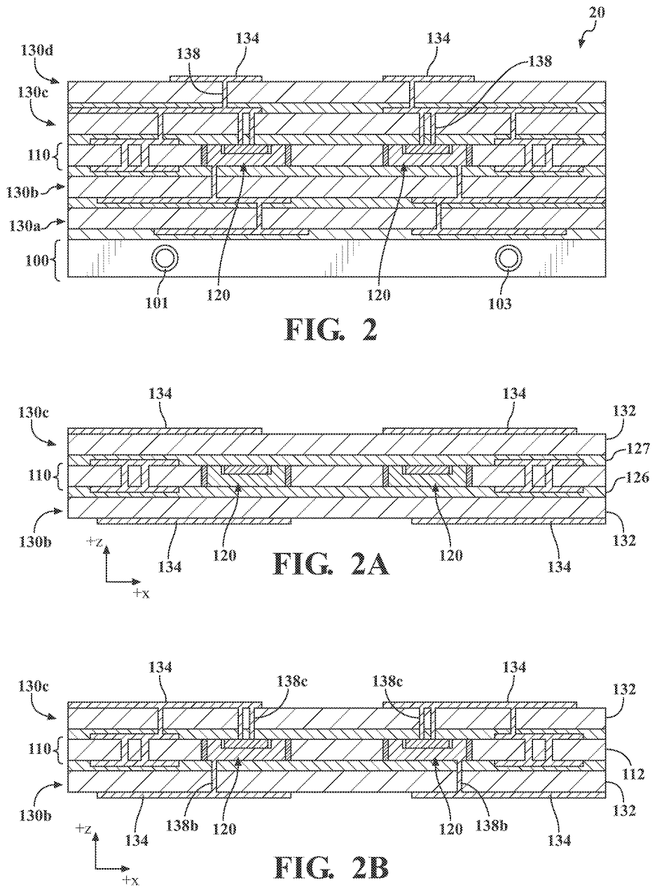

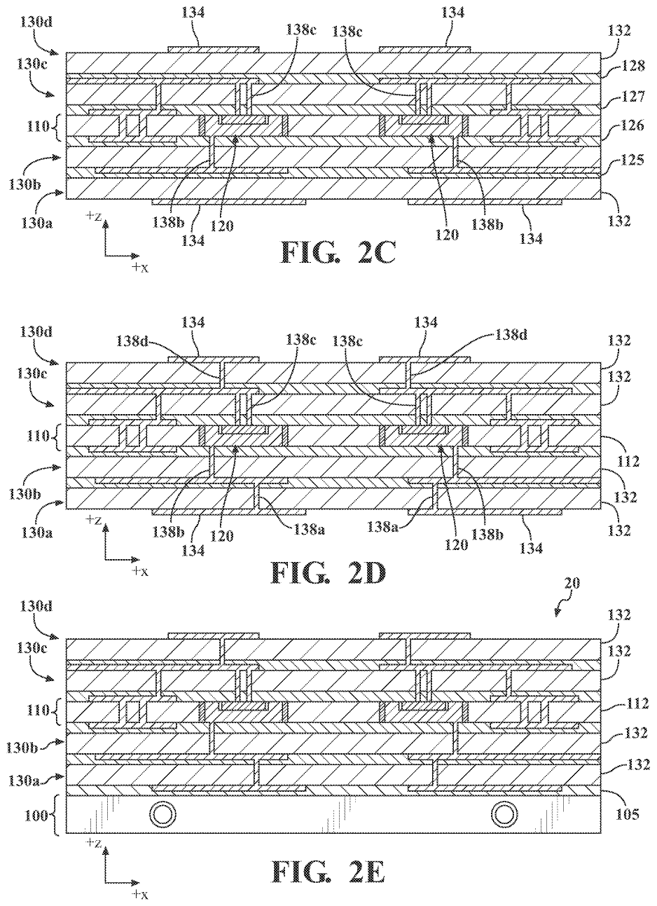

Referring now to FIG. 2, a cross-sectional view of a symmetric PCB in the form of a glass-based chip-embedded PCB 20 is shown. The glass-based chip-embedded PCB 20 includes the cold plate 100, the glass-based core layer 110 and a plurality of glass-based circuit board layers 130a-130d (collectively referred to herein as “glass-based circuit board layers 130”). However, and unlike the glass-based chip-embedded PCB 10, the glass-based core layer 110 is disposed or positioned evenly between the glass-based circuit board layers 130a-130d such the glass-based chip-embedded PCB 20 is symmetric. That is, two glass-based circuit board layers (130a, 130b) are positioned and bonded below (−z direction) the glass-based core layer 110 and two glass-based circuit board layers (130c, 130d) are positioned and bonded above (+z direction) the glass-based core layer 110.

Referring to FIGS. 2A-2E, steps for the manufacture of the glass-based chip-embedded PCB 20 are illustrated. Particularly, and with reference to FIG. 2A, one step of manufacturing the glass-based chip-embedded PCB 20 includes bonding a glass-based circuit board layer 130b to the first surface 111 of the glass-based core layer 110 (i.e., glass substrate 112) with an electrically insulting bonding layer 126 and bonding a glass-based circuit board layer 130c to the second surface 113 of the glass-based core layer 110 with an electrically insulating bonding layer 127.

It should be understood that the predefined conductive pattern 134p of the glass-based circuit board layer 130b and/or the predefined conductive pattern 134p of the glass-based circuit board layer 130c can be etched and formed from a conductive layer 114 before bonding the glass-based circuit board layer 130b and/or the glass-based circuit board layer 130c to the glass-based core layer 110. In the alternative, the predefined conductive pattern 134p of the glass-based circuit board layer 130b and/or the predefined conductive pattern 134p of the glass-based circuit board layer 130c can be etched and formed after bonding the respective glass layer 132 that forms the glass-based circuit board layer 130b and/or the glass-based circuit board layer 130c to the glass-based core layer 110. It should also be understood that the glass-based core layer 110 can be formed of fabricated per the steps described above with respect to FIGS. 1A-1E and the glass-based circuit board layers 130b, 130c can be formed or fabricated per the steps described with reference to FIG. 1H. In addition, conductive through vias 138b, 138c are formed through the glass-based circuit board layers 130b, 130c, respectively (FIG. 2B). And as illustrated in FIG. 2B, in some variations one or more of the conductive through vias 138b are in direct contact with a bare die 122 and one or more of the conductive through vias 138c are in direct contact with a heat spreader 124. In this manner, two glass-based circuit board layers 130 are bonded to the glass-based core layer 110 symmetrically.

Referring to FIG. 2C, additional steps for the manufacture of the glass-based chip-embedded PCB 20 include bonding a glass-based circuit board layer 130a to the lower (−z direction) of the glass-based circuit board layer 130b with an electrically insulating bonding layer 125 and bonding a glass-based circuit board layer 130d to the upper (+z direction) of the glass-based circuit board layer 130d with an electrically insulating bonding layer 128 (FIG. 2C).

It should be understood that the predefined conductive pattern 134p of the glass-based circuit board layer 130a and/or the predefined conductive pattern 134p of the glass-based circuit board layer 130d can be etched and formed from a conductive layer 114 before bonding the glass-based circuit board layer 130a and/or the glass-based circuit board layer 130d to the glass-based circuit board layer 130b and/or the glass-based circuit board layer 130c, respectively. In the alternative, the predefined conductive pattern 134p of the glass-based circuit board layer 130a and/or the predefined conductive pattern 134p of the glass-based circuit board layer 130d can be etched and formed after bonding the respective glass layer 132 that forms the glass-based circuit board layer 130a and/or the glass-based circuit board layer 130d to the glass-based circuit board layer 130b and/or the glass-based circuit board layer 130c, respectively.

Referring to FIG. 2D, additional steps include forming conductive through vias 138a, 138d through the glass-based circuit board layers 130a, 130d, respectively. Then, and with reference to FIG. 2E, the upper (+z direction) surface of the cold plate 100 is bonded to the lower (−z direction) surface of the glass-based circuit board layer 130a with an electrically insulating bonding layer 105. In this manner, the glass-based chip-embedded PCB 20 is manufactured.

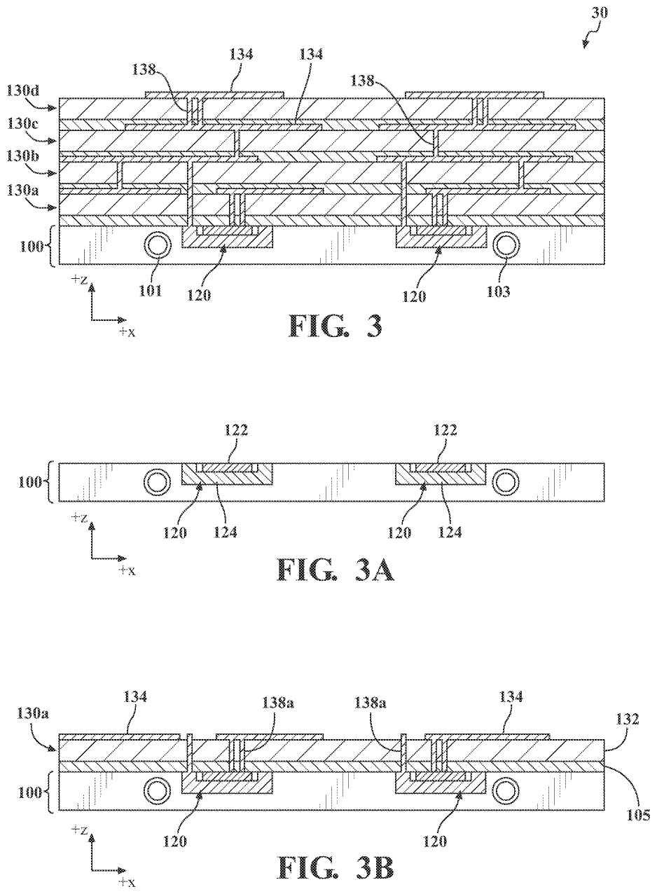

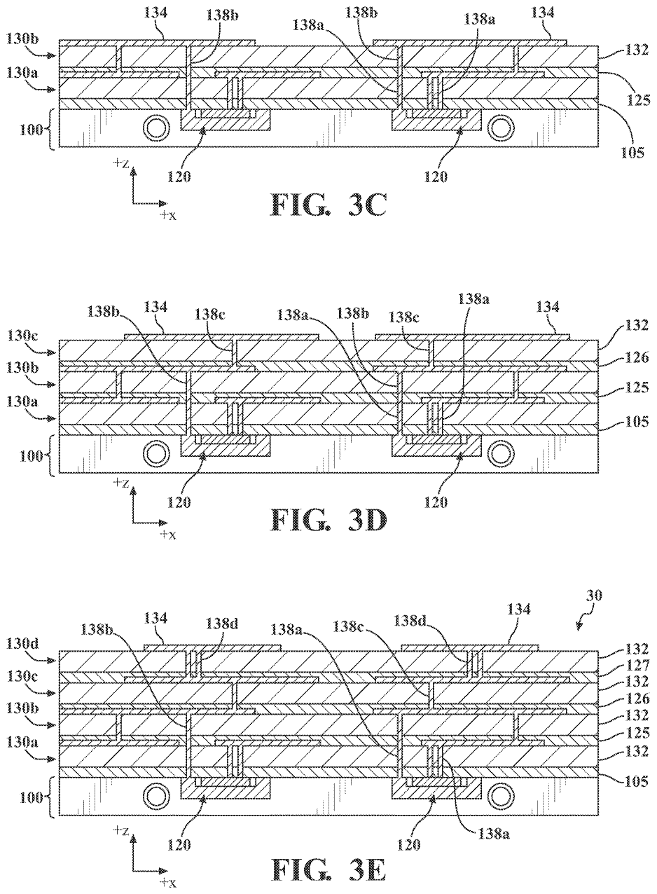

Referring now to FIG. 3, a cross-sectional view of an asymmetric PCB in the form of a glass-based chip-embedded PCB 30 is shown. The glass-based chip-embedded PCB 20 includes the cold plate 100 and a plurality of glass-based circuit board layers 130a-130d. However, and unlike the glass-based chip-embedded PCB 10, the bare die-heat spreader assemblies 120 are embedded in the cold plate 100.

Referring to FIGS. 3A-3E, steps for the manufacture of the glass-based chip-embedded PCB 30 are illustrated. Particularly, and with reference to FIG. 3A, one step of manufacturing the glass-based chip-embedded PCB 30 includes bonding two or more bare die-heat spreader assemblies 120 to the cold plate 100. In some variations, the cold plate 100 includes or is fabricated with heat spreader caves 109 and the heat spreaders 124 of the bare die-heat spreader assemblies 120 are disposed within and bonded to the heat spreader caves 109 with a bonding layer 107. Also, the bonding layer 107 is a dielectric layer that is thermally conductive but electrically insulating.

Referring to FIG. 3B, other steps for the manufacture of the glass-based chip-embedded PCB 30 include bonding a glass-based circuit board layer 130a to an upper (+z direction) surface of the cold plate 100, with the bare die-heat spreader assemblies 120, with an electrically insulating bonding layer 105 and forming conductive through vias 138a. It should be understood that the predefined conductive pattern 134p of the glass-based circuit board layer 130a can be etched and formed from a conductive layer 114 before bonding the glass-based circuit board layer 130a to the cold plate 100. In the alternative, the predefined conductive pattern 134p of the glass-based circuit board layer 130a can be etched and formed from a conductive layer 114 after bonding the glass layer 132 that forms the glass-based circuit board layer 130a to the cold plate 100. And as illustrated in FIG. 3B, in some variations one or more of the conductive through vias 138a is in direct contact with a bare die 122 and one or more of the conductive through vias 138 is in direct contact with a heat spreader 124. In this manner, the glass-based circuit board layer 130a is bonded to the cold plate 100 and the bare die-heat spreader assemblies 120.

Referring to FIG. 3C, other steps for the manufacture of the glass-based chip-embedded PCB 30 include bonding a glass-based circuit board layer 130b to an upper (+z direction) surface of the glass-based circuit board layer 130a with an electrically insulating bonding layer 125 and forming conductive through vias 138b. It should be understood that the predefined conductive pattern 134p of the glass-based circuit board layer 130b can be etched and formed from a conductive layer 114 before bonding the glass-based circuit board layer 130b to the glass-based circuit board layer 130a. In the alternative, the predefined conductive pattern 134p of the glass-based circuit board layer 130b can be etched and formed from a conductive layer 114 after bonding the glass layer 132 that forms the glass-based circuit board layer 130b to the glass-based circuit board layer 130a. And as illustrated in FIG. 3C, in some variations one or more of the conductive through vias 138b is in direct contact with one or more of the conductive through vias 138a such that one or more of the conductive through vias 138b is in direct contact with a heat spreader 124.

And referring to FIGS. 3D-3E, other steps for the manufacture of the glass-based chip-embedded PCB 30 include bonding a glass-based circuit board layer 130c to an upper (+z direction) surface of the glass-based circuit board layer 130b with an electrically insulating bonding layer 126 and forming conductive through vias 138c, and bonding a glass-based circuit board layer 130d to an upper (+z direction) surface of the glass-based circuit board layer 130c with an electrically insulating bonding layer 127 and forming conductive through vias 138d. In this manner, the glass-based chip-embedded PCB 30 is manufactured.

It should be understood that the predefined conductive pattern 134p of the glass-based circuit board layer 130c can be etched and formed from a conductive layer 114 before bonding the glass-based circuit board layer 130c to the glass-based circuit board layer 130b. In the alternative, the predefined conductive pattern 134p of the glass-based circuit board layer 130c can be etched and formed from a conductive layer 114 after bonding the glass layer 132 that forms the glass-based circuit board layer 130c to the glass-based circuit board layer 130b. Similarly, it should be understood that the predefined conductive pattern 134p of the glass-based circuit board layer 130d can be etched and formed from a conductive layer 114 before bonding the glass-based circuit board layer 130d to the glass-based circuit board layer 130c. In the alternative, the predefined conductive pattern 134p of the glass-based circuit board layer 130d can be etched and formed from a conductive layer 114 after bonding the glass layer 132 that forms the glass-based circuit board layer 130d to the glass-based circuit board layer 130c.

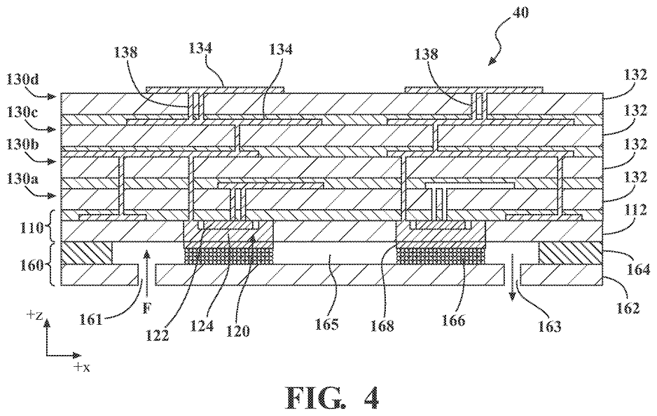

Referring to FIG. 4, a cross-sectional view of another asymmetric PCB in the form of a glass-based chip-embedded PCB 40 is shown. The glass-based chip-embedded PCB 40 includes the glass-based core layer 110 and the plurality of glass-based circuit board layers 130a-130d. However, and unlike the glass-based chip-embedded PCB 10, the cold plate 100 is in the form of or is replaced by a glass manifold 160 bonded and sealed to the glass-based core layer 110. The glass manifold 160 includes a glass substrate 162 and a spacer(s) 164 such that a chamber 165 is formed or defined between the glass substrate 162 and the glass-based core layer 110. In some variations, the glass spacer(s) 164 is a separate component from and bonded to (and between) the glass substrate 112 of the glass-based core layer 110 and the glass substrate 162 of the glass manifold 160. In other variations, the glass spacer(s) 164 is integral with the glass substrate 112 (not shown) and the glass substrate 162 is bonded to a lower (−z direction) surface of the spacer(s) 164. And in at least one variation, the glass spacer(s) 164 is integral with the glass substrate 162 (not shown) and the glass substrate 112 is bonded to an upper (+z direction) surface of the spacer(s) 164. As used herein, the term “integral” refers to a component or feature in the drawings (e.g., a spacer 164) being formed from the same piece of material as another component of feature in the drawings (e.g., the glass substrate 112 or the glass substrate 162). State differently, and for example, in some variations the spacer(s) 164 and the glass substrate 112 are formed from a single piece of glass with no interface or surface therebetween (not shown in the FIG. 4).

The glass manifold 160 includes an inlet 161 (e.g., in the glass substrate 162) and an outlet 163 (e.g., in the glass substrate 162). And in some variations, a porous layer 166 is disposed between the heat spreader 124 of a bare die-heat spreader assembly 120 and the glass substrate 162 such that fluid ‘F’ flowing through the inlet and entering the chamber 165 flows through the porous layer 166 and exits the chamber 165 through the outlet 163. In at least one variation, the porous layer 165 is bonded to the heat spreader 124 with a bonding layer 168. And it should be understood that the fluid flowing through the chamber 165 and the porous layer 166 removes heat from the heat spreader 124. Non-limiting examples of the porous layer 166 include a hollow sphere layer as described in U.S. Pat. No. 10,347,601 which is incorporated herein in its entirety by reference, a metal foam layer, and a sintered metal particle layer, among others.

The preceding description is merely illustrative in nature and is in no way intended to limit the disclosure, its application, or its uses. Work of the presently named inventors, to the extent it may be described in the background section, as well as aspects of the description that may not otherwise qualify as prior art at the time of filing, are neither expressly nor impliedly admitted as prior art against the present technology.

The figures illustrate the functionality and operation of possible implementations of methods and systems according to various forms or variations. In this regard, each block in the block diagram may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

As used herein, the phrase at least one of A, B, and C should be construed to mean a logical (A or B or C), using a non-exclusive logical “or.” It should be understood that the various steps within a method may be executed in different order without altering the principles of the present disclosure. Disclosure of ranges includes disclosure of all ranges and subdivided ranges within the entire range.

The headings (such as “Background” and “Summary”) and sub-headings used herein are intended only for the general organization of topics within the present disclosure and are not intended to limit the disclosure of the technology or any aspect thereof. The recitation of multiple variations or forms having stated features is not intended to exclude other variations or forms having additional features, or other variations or forms incorporating different combinations of the stated features.

As used herein the term “about” when related to numerical values herein refers to known commercial and/or experimental measurement variations or tolerances for the referenced quantity. In some variations, such known commercial and/or experimental measurement tolerances are +/−10% of the measured value, while in other variations such known commercial and/or experimental measurement tolerances are +/−5% of the measured value, while in still other variations such known commercial and/or experimental measurement tolerances are +/−2.5% of the measured value. And in at least one variation, such known commercial and/or experimental measurement tolerances are +/−1% of the measured value.

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all possible combinations of one or more of the associated listed items. As an example, the phrase “at least one of A, B, and C” includes A only, B only, C only, or any combination thereof (e.g., AB, AC, BC, or ABC).

As used herein, the terms “comprise” and “include” and their variants are intended to be non-limiting, such that recitation of items in succession or a list is not to the exclusion of other like items that may also be useful in the devices and methods of this technology. Similarly, the terms “can” and “may” and their variants are intended to be non-limiting, such that recitation that a form or variation can or may comprise certain elements or features does not exclude other forms or variations of the present technology that do not contain those elements or features.

The broad teachings of the present disclosure can be implemented in a variety of forms. Therefore, while this disclosure includes particular examples, the true scope of the disclosure should not be so limited since other modifications will become apparent to the skilled practitioner upon a study of the specification and the following claims. Reference herein to one variation, or various variations means that a particular feature, structure, or characteristic described in connection with a form or variation or particular system is included in at least one variation or form. The appearances of the phrase “in one variation” (or variations thereof) are not necessarily referring to the same variation or form. It should also be understood that the various method steps discussed herein do not have to be conducted in the same order as depicted, and not each method step is required in each variation or form.

The foregoing description of the forms and variations has been provided for purposes of illustration and description. It is not intended to be exhaustive or to limit the disclosure. Individual elements or features of a particular form or variation are generally not limited to that particular form or variation, but, where applicable, are interchangeable and can be used in a selected form or variation, even if not specifically shown or described. The same may also be varied in many ways. Such variations should not be regarded as a departure from the disclosure, and all such modifications are intended to be included within the scope of the disclosure.

What is claimed is:

1. A method comprising:
bonding a bare die to a heat spreader;
bonding the heat spreader to a cold plate;
forming an electrically conductive layer on a glass substrate;
etching a conductive pattern on the glass substrate;
forming through conductive vias in the glass substrate;
bonding a first surface of the glass substrate to the cold plate;
bonding a plurality of additional glass substrates with conductive patterns to a second side of the glass substrate; and
forming through conductive vias in the plurality of additional glass substrates such that an asymmetric glass-based chip-embedded printed circuit board is formed.

2. The method according to claim 1 further comprising forming a heat spreader cave in the cold plate, wherein the heat spreader is disposed within and bonded to the heat spreader cave in the cold plate.

3. The method according to claim 2, wherein the cold plate comprises a first surface and a second surface oppositely disposed from the first surface, the heat spreader cave extends from the second surface towards the first surface, and the first surface of the glass substrate is bonded to the second surface of the cold plate.

4. The method according to claim 3, wherein the through conductive vias formed in the glass substrate comprise at least one through conductive via in direct contact the bare die and at least one other through conductive via in direct contact with the heat spreader.

5. The method according to claim 4, wherein the heat spreader is selected from the group consisting of a metal heat spreader, a carbon heat spreader, and a metal-carbon composite heat spreader.

6. The method according to claim 5, wherein the cold plate is selected from the group consisting of a fluid cooled cold plate, a two-phase cooling device, an air-cooled heat sink, and a glass manifold.

7. The method according to claim 6 further comprising a dielectric layer between the heat spreader and the heat spreader cave.

8. The method according to claim 7, wherein the plurality of additional glass substrates with conductive patterns are bonded to a second surface, oppositely disposed from the first surface, of the glass substrate with glass frit.

9. The method according to claim 1 further comprising forming a heat spreader cave in the glass substrate, wherein the heat spreader is disposed within and bonded to the heat spreader cave in the glass substrate.

10. The method according to claim 9 further comprising forming a dielectric layer between the heat spreader and the cold plate.

11. The method according to claim 10, wherein the through conductive vias formed in the plurality of additional glass substrates comprise at least one through conductive via in direct contact the bare die and at least one other through conductive via in direct contact with the heat spreader.

12. The method according to claim 11, wherein the heat spreader is selected from the group consisting of a metal heat spreader, a carbon heat spreader, and a metal-carbon composite heat spreader.

13. The method according to claim 12, wherein the metal heat spreader is a copper containing heat spreader.

14. The method according to claim 13, wherein the cold plate is selected from the group consisting of a fluid cooled cold plate, a two-phase cooling device, an air-cooled heat sink, and a glass manifold.

15. The method according to claim 14, wherein the plurality of additional glass substrates with conductive patterns are bonded to the second side of the glass substrate with glass frit.

16. A method comprising:
bonding a bare die to a heat spreader;
bonding the heat spreader to a heat spreader cave in a cold plate;
forming an electrically conductive layer on a glass substrate;
etching a conductive pattern on the glass substrate;
forming through conductive vias in the glass substrate;
bonding a first side of the glass substrate to the cold plate;
bonding a plurality of additional glass substrates with conductive patterns to a second side of the glass substrate; and
forming through conductive vias in the plurality of additional glass substrates such that an asymmetric glass-based chip-embedded printed circuit board is formed.

17. The method according to claim 16, wherein the cold plate comprises a first surface and a second surface oppositely disposed from the first surface, and the heat spreader cave extends from the second surface towards the first surface.

18. The method according to claim 17, wherein the through conductive vias formed in the glass substrate comprise at least one through conductive via in direct contact the bare die and at least one other through conductive via in direct contact with the heat spreader.

19. A method comprising:
forming an electrically conductive layer on a glass substrate;
etching a conductive pattern on the glass substrate;
forming through conductive vias in the glass substrate;
forming a heat spreader cave in the glass substrate;
bonding a bare die to a heat spreader;
bonding the heat spreader to the heat spreader cave;
bonding a first side of the glass substrate to a cold plate;
bonding a plurality of additional glass substrates with conductive patterns to a second side of the glass substrate; and
forming through conductive vias in the plurality of additional glass substrates such that an asymmetric glass-based chip-embedded printed circuit board is formed.

20. The method according to claim 9 further comprising forming a dielectric layer between the glass substrate with the heat spreader and the cold plate, wherein the through conductive vias formed in the plurality of additional glass substrates comprise at least one through conductive via in direct contact the bare die and at least one other through conductive via in direct contact with the heat spreader.
